(19) United States
(12) Patent Application Publication
(10) Pub. No.: US 2024/0222114 A1
(43) Pub. Date: Jul. 4, 2024

(54) METHOD OF FORMING A CONFORMAL AND CONTINUOUS CRYSTALLINE SILICON NANOSHEET WITH IMPROVED ELECTRICAL PROPERTIES AT LOW DOPING LEVELS

(71) Applicant: L'Air Liquide, Societe Anonyme pour l'Etude et l’Exploitation des Procedes Georges Claude, Paris (FR)

(72) Inventors: Claudia Fafard, Newark, DE (US); Sana Rani, Newark, DE (US); Nathan Stafford, Newark, DE (US); Jean-Marc Girard, Paris (FR); Venkateswara R. Pallem, Branchburg, NJ (US)

(73) Assignees: L'Air Liquide, Societe Anonyme pour l'Etude et l'Exploitation des Procedes Georges Claude, Paris (FR); American Air Liquide, Inc., Fremont, CA (US)

(21) Appl. No.: 18/089,132

(22) Filed: Dec. 27, 2022

(51) Int. Cl. H01L 21/02; C23C 16/02; C23C 16/24; C23C 16/56; C30B 1/02; C30B 29/06

(52) U.S. Cl. CPC H01L 21/0262; C23C 16/0227; C23C 16/0272; C23C 16/24; C23C 16/56; C30B 1/023; C30B 29/06; H01L 21/02532; H01L 21/02576; H01L 21/02592; H01L 21/02645; H01L 21/02661; H01L 21/02667

(57) ABSTRACT

A method of forming a conformal and continuous crystalline Si film on a surface of a substrate comprises: exposing the substrate to a vapor of a first Si-containing precursor under a first temperature; allowing a seed film being formed onto the surface; exposing the substrate to a vapor of a second Si-containing precursor and a vapor of a dopant precursor under a second temperature; depositing a doped amorphous Si-containing film onto the seed film by a chemical vapor deposition (CVD) process; and annealing the substrate to crystalize the doped amorphous Si-containing film forming the conformal and continuous crystalline Si film on the surface. The first Si-containing precursor is (diisobutylamine)trisilane ((iBu)₂-N—(SiH₂)₂—SiH₃).

### TECHNICAL FIELD

The present invention is related to methods of forming an ultrathin conformal and continuous crystalline Si film or nanosheet on a surface of a substrate with improved electrical properties at a low doping level using a surface preparative Si-containing precursor, in particular, to methods of forming an ultrathin conformal and continuous crystalline Si film or nanosheet using (diisobutylamino)trisilane ((iBu)₂-N—(SiH₂)₂—SiH₃).

### BACKGROUND

With the ever shrinking dimensions of today's logic and memory devices, strict controls are necessary in the growth of critical layers of these devices. Using conventional materials/precursors control of such properties as layer thickness, conformality and final layer properties may not be possible due to inherent challenges. For example, silane, which is ubiquitous in the semiconductor industry, is known to have challenges to nucleate on certain substrates such as silicon dioxide. This presents a challenge when it is necessary to grow very thin Si films on such substrates. This requires either new precursors or processes to overcome the challenge.

Another issue to contend with is also the thermal budget of current and future devices. Lower thermal budgets are often desirable to reduce any effects or damage to underlying materials.

The required process temperatures for Si-containing material depositions are polarizing into ultra-low temp (around 100° C. for sacrificial, masking, protection layers) or very high temperature (over 600° C., mainly for 3D NAND memory), to protect substrate material, or to avoid thermal stress in followed process respectively. Current and future nodes continue to shrink and as a result, we are quickly approaching the physical limits of current chemistries and processes. Precise control in deposition of various layers has become critical, as we have moved towards single digit nm scales. To put into perspective, targeting a film of five nm is putting down a layer, which is only 25 atoms in thickness. These films thus need to have a high degree of control of composition, conformity and roughness when depositing within a structure that has an opening that has perhaps 60-100 nm and a depth of 6 um or greater.

Traditional 3DNAND utilized poly-Si material as the channel but as the number of memory layers increase the current through the poly-Si channel decreases and is unsatisfactory for continued scaling. Charge tunnels through a thin tunnel dielectric layer between the channel and the silicon nitride for the program and erase. The conduction in poly-Si channel is hampered by grain size and by scattering events at grain boundaries and charged defects. Furthermore, the current requirement for reading operations decreases as the number of stacked memory layers increases.

Traditional chemistries for growing the Si channel film include chloro and hydrido silanes. The most inherent issue with using hydrido silanes such as SiH₄ and Si₂H₆ is their poor sticking coefficients towards SiO₂, the tunneling oxide, and this leads to an incubation period and island growth. This means that continuous films may be much thicker than targeted specifications. This is somewhat overcome by a few different approaches. Instead of a hydrido silane the bulk Si film can be grown using chlorosilane molecules such as Si₂Cl₆ in a reducing atmosphere. Drawbacks include the incorporation of Cl into the film and potential etching of other areas due to the formed HCl. Another method would be to alter the surface termination using, what has been termed, a seed layer. This leaves a surface that is more aptly favorable towards more continuous film growth versus island growth.

ECS Transactions, 3 (2) 203-215 (2006) discloses Silcore (Si₃H₈) deposition occurs at lower temperatures than that observed for Silane. Additionally, silcore films are shown to have low surface roughness in comparison to Silane films.

U.S. Pat. No. 5,786,027 discloses a method comprises a LPCVD process in which at least two silicon source gases having different adsorption characteristics (termed as “sticking coefficients”) are used to grow a polysilicon thin film on a substrate. The different silicon source gases (silane, SiH₄, disilane, Si₂H₆, trisilane, Si₃H₈ or dichlorosilane, SiH₂Cl₂) can be injected into a LPCVD reaction chamber at the same time or in a sequence. This method forms a polycrystalline film with grain boundaries that are not continuous across the full thickness of the film.

US2006205194 discloses a method of depositing a doped crystalline Si-containing film, comprising: providing a substrate disposed within a chamber; intermixing Trisilane and a dopant precursor to form a feed gas, the dopant precursor comprising an electrical dopant; contacting the substrate with the feed gas under chemical vapor deposition conditions; and depositing a doped crystalline Si-containing film onto the substrate at a deposition rate of at least about 10 nm per minute, the doped crystalline Si-containing film having a resistivity of about 1 m ohm cm or less. Preferably, the doped crystalline Si-containing film comprises at least about 3×10²⁰ atoms/cc of the electrical dopant.

US 2007141812 discloses a method comprises depositing a silicon layer on a plurality of substrates in a batch process chamber by exposing the substrates to Trisilane. The silicon layer is doped by exposing the substrates to an n-type dopant precursor during at least part of the deposition of the silicon layer.

US2009072294 discloses a method of manufacturing a non-volatile memory device. In the method, a tunnel oxide layer is first formed on a suitable substrate. A polysilicon layer having a thickness of about 3.5 nm to about 20 nm is then formed on the tunnel oxide layer by using a Trisilane (Si₃H₈) gas and by a low pressure chemical vapor deposition (LPCVD) process. A surface of the polysilicon layer formed according to this method desirably may have an Rq roughness of about 0.1 nm to about 0.4 nm. The LPCVD process may be performed at a temperature of about 400° C. to about 500° C. and at a pressure of about 100 mTorr to about 1000 mTorr. The resulting amorphous silicon layer may then be crystallized by thermally treating the amorphous silicon layer at a temperature of about 550° C. to about 900° C. This polysilicon layer having a superior morphology and a superior thickness uniformity relative to those formed by conventional techniques.

U.S. Pat. No. 9,382,269 and U.S. Ser. No. 10/494,387 disclose aminosilanes are used as precursors for vapor deposition methods of silicon-containing films. The method includes introducing the vapor of the disclosed precursors into a reactor having at least one substrate disposed therein: and using a vapor deposition process to deposit at least part of the disclosed precursor onto the substrate to form a Si-containing layer. The film obtained by a vapor deposition method can be further treated by various methods such as annealing, reactive annealing, UV curing, e-beam curing and radical annealing. The film composition and structure can be significantly affected by this step.

Yagnamurthy's dissertation (Effect of Grain Structure and Doping on the Mechanical Properties of Polysilicon Thin Films for Mems, 2013) discloses silicon films deposited at greater than a critical temperature of ˜580° C. form crystalline structure those deposited at lower temperatures are amorphous. The grain size can be enhanced by annealing the deposited films post deposition at temperatures greater than 580° C. Larger grains are grown at lower temperatures than at higher temperatures due to the crystallization rate being faster than the nucleation rate.

Song, et al. (The substrate effects on Kinetics and Mechanism of Solid-Phase Crystallization of Amorphous Silicon Thin Films, ETRI Journal, Volume 19, Number 1, April 1997) disclose crystallization kinetics and mechanism for a-Si deposited using LPCVD using Si₂H₆ was studied especially the substrate effects. They found that the surface plays a significant role in the nucleation mechanism in the crystallization process. A smooth substrate surface may relieve the structural disorder of the a-Si film as well as when deposited at low temperatures High temperature deposition may have interface induced crystallization. Increased structural disorder results in less grain growth.

WO 2021/257927 discloses self-assembling monolayer (SAM) monomers or precursors having a Si-based tail or backbone (SiT-SAM) that contains no Si—C bonds, their syntheses, and their applications in surface preparations in film forming processes, in particular, to the SiT-SAM monomers selected from the group consisting of Si—C-free polysilane-based tail SiT-SAMs monomers and trisilylamine-based tail SiT-SAMs monomers. (Diisobutylamino)trisilane and other molecules are disclosed to form a SAM layer by reacting with the —OH surface. Further, SAM monomers that are not based on carbon backbones could also be used for additional applications such as seed layers to enhance nucleation of CVD and ALD processes, due to their increased reactivity to specific chemical families, metal halides for example. Disclosed is a method of forming a SAM layer followed by a deposition process including ALD or CVD.

US20140187024 discloses a method of forming a seed layer as a seed of a thin film on an underlayer, which includes: forming a first seed layer on a surface of the underlayer by heating the underlayer, followed by supplying an aminosilane-based gas onto the surface of the heated underlayer; and forming a second seed layer on the surface of the underlayer with the first seed layer formed thereon by heating the underlayer, followed by supplying a disilane or higher order silane-based gas onto the surface of the heated underlayer. The aminosilane may include the following molecules which containing one Si atom: butylaminosilane (BAS), bis(tertiary-butylamino)silane (BTBAS), dimethylaminosilane (DMAS), bis(dimethylamino)silane (BDMAS), tri(dimethylamino)silane (TDMAS), diethylaminosilane (DEAS), dipropylaminosilane (DPAS), bis(diethylamino)silane (BDEAS), diisopropylaminosilane (DIPAS), as well as hexakis(ethylamino)disilane and formula ((R1R2)N)ₙSi_{X}H_{2X+2-n-m}(R3)ₘ, and ((R1R2)N)ₙSi_{X}H_{2X-n-m}(R3)ₘ where n is the number of amino groups, which is a natural number of 1 to 6, m is the number of alkyl groups, which is zero or a natural number of 1 to 5, R1, R2, R3=CH₃, C₂H₅, C₃H₇, R1, R2 and R3 may be equal to each other, or may not be equal to each other. R3 may be Cl or F. X is a natural number of equal to or greater than one. In the first embodiment, diisopropylaminosilane (DIPAS) was used as the aminosilane-based gas. The second seed layer could be formed using disilane or other silicon hydride represented by the formula SiₘH₂ₘ₊₂ or SiₙH₂ₘ.

There is a need for new chemistries and processes to produce ultra-thin conformal, continuous, uniform, smooth crystalline doped poly-Si layers with low resistivity and good mobility through use of a seed layer and bulk film deposition chemistries.

### SUMMARY

Disclosed is a method of forming a conformal and continuous crystalline Si film on a surface of a substrate, the method comprising:
i) exposing the substrate to a vapor of a first Si-containing precursor under a first temperature;
ii) allowing a seed film being formed onto the surface;
iii) exposing the substrate to a vapor of a second Si-containing precursor and a vapor of a dopant precursor under a second temperature;
iv) depositing a doped amorphous Si-containing film onto the seed film by a chemical vapor deposition (CVD) process; and
v) annealing the substrate to crystalize the doped amorphous Si-containing film forming the conformal and continuous crystalline Si film on the surface. The disclosed method may include one or more of the following features:
further comprising, prior to annealing the substrate at v), exposing the substrate to air for a period sufficient to form a native oxide layer on the doped amorphous Si-containing film;
the period ranging from 1 minute to 48 hours;
further comprising, prior to exposing the substrate at i), cleaning the surface of the substrate with SC-1, HF, RC-1, or RC-2; and heating the substrate to an elevated temperature, wherein the first temperature is lower than the elevated temperature;
the first Si-containing precursor having a general formula:

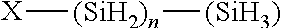

wherein n=1 to 4; X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.
the first Si-containing precursor being (diisobutylamino)trisilane ((iBu)₂-N—(SiH₂)₂—SiH₃) has the following structure:

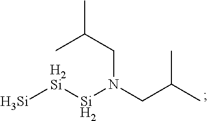

the first Si-containing precursor being X-substituted polysilanes or trisilylamines, wherein X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group;
the first Si-containing precursor being 1,1,1,2,2,2-hexachlorodisilane ((SiCl₃)₂, HCDS, CAS No.: 13465-77-5);
the second Si-containing precursor having a general formula:

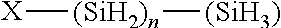

wherein n=0 to 4; X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group;
the second Si-containing precursor being selected from silane, disilane, trisilane, tetrasilane, pentylsilane, (diisobutylamino)trisilane ((iBu)₂-N—(SiH₂)₂—SiH₃), 1,1,1,2,2,2-hexachlorodisilane ((SiCl₃)₂, HCDS, CAS No.: 13465-77-5), or dichlorosilane (H₂SiCl₂, DCS, CAS No.: 4109-96-0);
the second Si-containing precursor being silane;
the second Si-containing precursor being disilane;
the second Si-containing precursor being trisilane;
the second Si-containing precursor being tetrasilane;
the second Si-containing precursor being pentylsilane;
the second Si-containing precursor being (diisobutylamino)trisilane;
the second Si-containing precursor being 1,1,1,2,2,2-hexachlorodisilane ((SiCl₃)₂, HCDS, CAS No.: 13465-77-5);
the second Si-containing precursor being dichlorosilane (H₂SiCl₂, DCS, CAS No.: 4109-96-0);
the second Si-containing precursor being the same as the first Si-containing precursor;
the dopant precursor selected from PH₃, AsH₃, P(SiH₃)₃, P(Si₂H₅)₃, As(SiH₃), As(SiH₃)₃, P(SiH₃)₂(Si₂H₅), BF₃, B₂H₆, B₅H₉ or BCls being carried by an inert gas;
the dopant precursor being PH₃ carried by an inert gas;
the dopant precursor being BF₃ carried by an inert gas;
the doped amorphous Si-containing film on the seed film being conformal;
the conformal and continuous crystalline Si film having a continuous thickness ranging from approximately 2 to approximately 100 nm;
the conformal and continuous crystalline Si film having a continuous thickness ranging from approximately 2 to approximately 35 nm;
the conformal and continuous crystalline Si film having a continuous thickness ranging from approximately 2 to approximately 20 nm;
the conformal and continuous crystalline Si film having a continuous thickness ranging from approximately 2 to approximately 10 nm;
the conformal and continuous crystalline Si film having a continuous thickness ranging from approximately 2 to approximately 5 nm;
the conformal and continuous crystalline Si film having a resistivity of about 0.2 Ω·cm or less and grain size of 20 nm or greater;
an electrical dopant in the conformal and continuous crystalline Si film ranging from about 1E17 to 1E20 atoms/cm³;
an electrical dopant in the conformal and continuous crystalline Si film ranging from about 1E18 to 1E19 atoms/cm³;
the first temperature ranging from 20° C. to 350° C.;
the first temperature ranging from 100° C. to 300° C.;
the second temperature ranging from 20° ° C. to 700° C.;
the second temperature ranging from 300° ° C. to 600° C.;
an annealing temperature ranging from 200° ° C. to approximately 1200° C.;
an annealing temperature being approximately 650° C.; and
a deposition pressure ranging from 0 to 100 Torr.

Also disclosed is a method of forming a conformal and continuous crystalline Si film on a surface of a substrate, the method comprising:
a) exposing the substrate to (diisobutylamino)trisilane at a temperature of 200° C.;
b) allowing a Si-containing seed film being formed onto the surface;
c) exposing the substrate to trisilane and 1% PH₃ gas carried by N₂ at a temperature of 410° C.;
d) depositing a doped amorphous Si-containing film onto the Si-containing seed film by a chemical vapor deposition (CVD) process; and
e) annealing the substrate under a temperature 650° C. to crystalize the doped amorphous Si-containing film forming the conformal and continuous crystalline Si film on the surface. The disclosed method may include one or more of the following features:
further comprising, prior to annealing the substrate at v), exposing the substrate to air to form a native oxide layer on the doped amorphous Si-containing film;
further comprising, prior to exposing the substrate at i), cleaning the surface of the substrate with SC-1, and heating the substrate to a temperature of 400° C.;
the doped amorphous Si-containing film on the Si-containing seed film being conformal;
the conformal and continuous crystalline Si film having a continuous thickness ranging from approximately 2 to approximately 100 nm;
the conformal and continuous crystalline Si film having a continuous thickness ranging from approximately 2 to approximately 35 nm;
the conformal and continuous crystalline Si film having a continuous thickness ranging from approximately 2 to approximately 20 nm;
the conformal and continuous crystalline Si film having a continuous thickness ranging from approximately 2 to approximately 10 nm;
the conformal and continuous crystalline Si film having a continuous thickness ranging from approximately 2 to approximately 5 nm;
the conformal and continuous crystalline Si film having a resistivity of about 0.2 Ω·cm or less and grain size of 20 nm or greater;
an electrical dopant in the conformal and continuous crystalline Si film being about 1E18 atoms/cm³; and
a deposition pressure ranging from 0 to 100 Torr.

### Notation and Nomenclature

The following detailed description and claims utilize a number of abbreviations, symbols, and terms, which are generally well known in the art, and include:

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° ° C. to approximately 25° C.

The term “wafer” or “patterned wafer” refers to a wafer having a stack of silicon-containing films on a substrate and a patterned film on the stack of silicon-containing films formed for pattern etch.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (including, but not limited to, crystalline, amorphous, porous, etc.), silicon containing layers (including, but not limited to, SiO₂, SiN, SiON, SiCOH, etc.), metal or metal containing layers (including, but not limited to, copper, cobalt, ruthenium, tungsten, platinum, palladium, nickel, ruthenium, gold, etc.) or combinations thereof. Furthermore, the substrate may be planar or patterned. The substrate may be an organic patterned Iodinated carbon layer film. The substrate may include layers of oxides which are used as dielectric materials in field effect transistor (FET) such as FinFET, MOFSET, GAAFET(Gate all-around FET), Ribbon-FET, Nanosheet, Forksheet FET, Complementary FET (CFET), MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. The substrate may be any solid that has functional groups on its surface that are prone to react with the reactive head of a SAM, and may include without limitation 3D objects or powders.

The term “wafer” or “patterned wafer” refers to a wafer having a stack of films on a substrate and at least the top-most film having topographic features that have been created in steps prior to the deposition of the indium containing film.

The term “processing” as used herein includes deposition of material or Iodinated carbon layer, patterning, exposure, development, etching, cleaning, and/or removal of the material or Iodinated carbon layer as required in forming a described structure.

The term “XRD” refers to x-ray diffraction, a spectroscopic technique using x-rays to measure the diffraction pattern of thin films when exposed to an x-ray. As atoms diffract x-rays, the atomic order and thus crystallinity and crystal size can be measured using this technique.

The term of “deposit” or “deposition” refers to a series of processes where materials at atomic or molecular levels are deposited on a wafer surface or on a substrate from a gas state (vapor) to a solid state as a thin layer. Chemical reactions are involved in the process, which occur after creation of a plasma of the reacting gases or activation the reacting gases by heat. The plasma may be a capacitively coupled plasma (CCP), generally created by radio frequency (RF) (alternating current (AC)) frequency or direct current (DC) discharge between two electrodes, the space between which is filled with the reacting gases. The plasma may also be microwave plasma. Suitable commercially available deposition tool include but are not limited to the ASM EPSILON™ EPITAXY or the Applied Materials Centura™ tool or other furnace, thermal, and epitaxy deposition tools. Deposit may also refer to a process of exposing the wafer to the liquid precursor (neat or dissolved in a solvent) by dip coating, immersion, or in a spin coating process.

The term “aspect ratio” refers to a ratio of the height of a trench (or aperture) to the width of the trench (or the diameter of the aperture).

The term “high aspect ratio (HAR)” refers to an aspect ratio ranging from approximately 1:1 to approximately 500:1, preferably from approximately 20:1 to approximately 400:1.

Note that herein, the terms “film”, “nanosheet” and “layer” may be used interchangeably. It is understood that a film may correspond to, or related to a layer or a nanosheet, and that the nanosheet may refer to the layer or the film. Furthermore, one of ordinary skill in the art will recognize that the terms “film”, “nanosheet”, or “layer” used herein refer to a thickness of some material laid on or spread over a surface and that the surface may range from as large as the entire wafer to as small as a trench or a line.

Note that herein, the terms “aperture”, “via”, “hole”, “structure” and “trench” may be used interchangeably to refer to an opening formed in a semiconductor structure.

The term “surface preparative precursor” used herein refers to a compound or gas that is used to deposit a seed layer on a surface prior to depositing a film on the surface. The seed layer, typically a thin layer material, creates nucleation sites to assist with film growth and improves electrical properties of the deposited film through annealing. The surface preparative precursor may have a reactive site that reacts with the atoms on the surface of the wafer forming a thin layer. The surface preparative precursor may either physisorbs or chemisorbs on the surface.

The term “resistivity” refers to bulk resistivity of wafer and film across a defined thickness.

The term “crystalline” refers to poly-crystalline and single crystalline.

The term “step coverage” refers to a ratio of thickness of film along the walls of a step to the thickness of the film at the bottom of a step.

Note that herein, the terms “step coverage” and “comformality” may be used interchangeably to refer to the quality of a deposited film formed in a semiconductor structure, pattern or 3D structure. It is the measure of how much coating is on the bottom or sidewall of a structure as compared to how much coating is at the top of a structure.

The term “nanosheet” refers to a two-dimensional nanostructure with thickness in a scale ranging from 1 to 100 nm.

The term “grain size” refers to the dimensional size or height occurring inside the grain or at the inner grain boundary of the crystalline grains formed in the crystalline film, or the maximum width of a gap in horizontal or vertical plane the grain could fill up, or the radius of minimum circle that contains the grain. Grains may grow in all directions but preferentially they grow parallel with the film. Grain may exhibit a symmetry that makes several directions to qualify.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

Note that herein, the terms “dope”, and “dopant” is used interchangeably to the process of incorporation of one or more elements into a film through various methods where that element may be chemically bond or physically bond. The element may be doped interstitial or substitutional within the film. As used herein, the term “doping” refers to the process of intentionally incorporating atoms of different elements into the film composition.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term which means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a flowchart of an exemplary disclosed method;

FIG. 2 is a block diagram of a 2″ Quartz tube (12″ single zone) hot walls CVD reactor used in the present invention;

FIG. 3 is a graph of step coverage of deposition at various temperature using (diisobutylamino)trisilane; and

FIG. 4 is a graph of growth rate (GR) and non-uniformity (%) (NU) vs temperature for the CVD using (diisobutylamino)trisilane.

### DESCRIPTION OF PREFERRED EMBODIMENTS

Disclosed is a method of forming a ultrathin conformal and continuous crystalline Si film or nanosheet on a substrate with excellent film and electrical properties at low doping levels using a surface preparative Si-containing precursor to form a “seed” layer between the formed film and the substrate. The disclosed method comprises using the surface preparative Si-containing precursor to form a first silicon layer (or the seed layer) and using another Si-containing precursor as a second deposition precursor to deposit a silicon layer on top of the first silicon-containing layer.

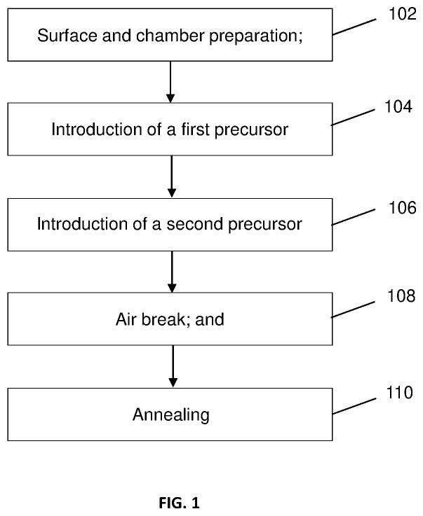

The disclosed method comprises the following steps, referring to FIG. 1. First, at Step 102, a substrate is provided whose surface is cleaned in order to remove surface contaminates, such as carbon, using wet or dry cleaning methods. After cleaning, the substrate is disposed in a reactor chamber. Under an inert gas flowing at a reduced pressure (i.e. vacuum), the reactor chamber is heated to an elevated temperature and stabilized, such as from 300° C. to 600° C., preferably 400° C., to optimize the surface hydroxyl density and to improve the quality of film deposition. At Step 104, a first deposition precursor, that is, a surface preparative Si-containing precursor, is introduced into the reaction chamber at a lower temperature than the elevated temperature, and the substrate is exposed to the surface preparative Si-containing precursor forming a conformal Si-containing seed layer on the surface. Alternative methods to vapor exposure may be used including dip coating the wafer in a neat or precursor/solvent mixture, or other methods such as spin coating the precursor on the wafer. Then at Step 106, a second deposition precursor, that is, a second Si-containing precursor, and a dopant precursor carried by an inert gas are introduced into the reaction chamber at the same or a different temperature as the seed layer deposition. Prior to introducing the second Si-containing precursor into the reaction chamber, a purging process using an inert gas may be performed. Then, a deposited film is formed on the surface and growth of the deposited film is obtained by contacting the substrate with the second Si-containing precursor and the dopant precursor under CVD conditions. Hence, a doped amorphous Si-containing ultrathin (nanosheet) conformal and continuous film having a thickness ranging from approximately 2 nm to approximately 100 nm, preferably ranging from approximately 2 nm to approximately 35 nm, is deposited onto the substrate. Here the second Si-containing precursor may or may not be the same as the surface preparative Si-containing precursor. That is, at Step 106, the surface preparative Si-containing precursor may be used as the second Si-containing precursor. Afterwards, at Step 108, the substrate is removed out of the reaction chamber and exposed to air for a period sufficient to form a native oxide layer, which is called air break here. Then, at Step 110, the substrate is disposed back into the reaction chamber so that an amorphous Si-containing film is crystallized under elevated temperatures by annealing to achieve a doped crystalline (i.e., poly-crystalline and/or single crystalline) Si film or nanosheet. The formed doped crystalline Si film or nanosheet may have a resistivity of about 0.2 Ω·cm or less and a grain size of 20 nm or greater, a roughness of Rq=0.5 nm or less, a conformity of 80% or greater, and impurity levels less than 5E19 atm/cm. Preferably the formed doped crystalline Si film or nanosheet comprises at least about 1E18 atoms/cm³ of electrical dopant.

The conformal and continuous Si-containing seed layer may support to improve the surface nucleation of the substrate material which may improve grain growth and result in a lower film resistivity. Furthermore, the deposition of the conformal Si seed layer on a patterned structure may improve the uniformity of the grain growth from the top portion of the pattern structure to the bottom of the pattern structure.

The disclosed surface preparative Si-containing precursor may have a general formula:

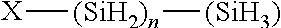

wherein n=1 to 4; X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.

The disclosed surface preparative Si-containing precursors may be (diisobutylamino)trisilane ((iBu)₂-N—(SiH₂)₂—SiH₃), having the following structure:

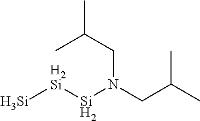

Synthesis of (diisobutylamine)trisilane may be referred to WO 2021/257927.

The disclosed surface preparative Si-containing precursor may be X-substituted polysilanes or trisilylamines, wherein X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.

The disclosed surface preparative Si-containing precursor may be 1,1,1,2,2,2-hexachlorodisilane ((SiCl₃)₂, HCDS, CAS No.: 13465-77-5).

The disclosed surface preparative Si-containing precursors have a surface reactive site to enhance the reactivity towards the surface, especially hydroxyl (—OH) groups.

The disclosed second Si-containing precursors may have a general formula:

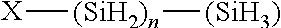

wherein n=0 to 4; X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.

The disclosed second Si-containing precursors may be selected from silane, disilane, trisilane, tetrasilane, pentylsilane, (diisobutylamino)trisilane ((iBu)₂-N—(SiH₂)₂—SiH₃), 1,1,1,2,2,2-hexachlorodisilane ((SiCl₃)₂, HCDS, CAS No.: 13465-77-5), or dichlorosilane (H₂SiCl₂, DCS, CAS No.: 4109-96-0).

The disclosed second Si-containing precursors may be trisilane.

To ensure process reliability, the disclosed surface preparative Si-containing precursors and the second Si-containing precursors may be purified by continuous or fractional batch distillation or sublimation prior to use to a purity ranging from approximately 93% by weight or w/w to approximately 100% w/w, preferably ranging from approximately 99% w/w to approximately 99.999% w/w, more preferably, ranging from approximately 99% w/w to approximately 100% w/w.

The disclosed precursors including the surface preparative Si-containing precursor, the Si-containing precursor, the dopant precursor may contain any of the following impurities: undesired congeneric species; solvents; chlorinated metal compounds; or other reaction products. In one alternative, the total quantity of these impurities is below 0.1% w/w.

Solvents, such as hexane, pentane, dimethyl ether, or anisole, may be used in the precursor's synthesis. The concentration of the solvent in the disclosed Si-containing precursors may range from approximately 0% w/w to approximately 5% w/w, preferably from approximately 0% w/w to approximately 0.1% w/w. Separation of the solvents from the precursor may be difficult if both have similar boiling points. Cooling the mixture may produce solid precursor in liquid solvent, which may be separated by filtration. Vacuum distillation may also be used, provided the precursor product is not heated above approximately its decomposition point.

In one alternative, the disclosed surface preparative Si-containing precursors and the second Si-containing precursors contain less than 5% v/v, preferably less than 1% v/v, more preferably less than 0.1% v/v, and even more preferably less than 0.01% v/v of any of its undesired congeneric species, reactants, or other reaction products.

In another alternative, the disclosed surface preparative Si-containing precursors and the second Si-containing precursors may contain between 5% v/v and 50% v/v of one or more of congeneric Si-containing precursors, reactants, or other reaction products, particularly when the mixture provides improved process parameters or isolation of the target compound is too difficult or expensive. For example, a mixture of two Si-containing precursors may produce a stable, liquid mixture suitable for vapor deposition.

The concentration of trace metals and metalloids in the disclosed surface preparative Si-containing precursors and the second Si-containing precursors each may range from approximately 0 ppb to approximately 100 ppb, and more preferably from approximately 0 ppb to approximately 10 ppb.

The disclosed method comprises a surface preparation step (102) prior to deposition. The surface preparation step includes wet cleaning the surface with SC-1, HF, RC-1, RC-2 and then dry cleaning the surface with O₃, plasma, or etching under a thermal temperature ranging from 200-800° C., preferably ranging from 200-500° C., a pressure ranging from 0 to 100 Torr, preferably ranging from 1 to 20 Torr. SC-1 wet clean is a cleaning solution of H₂O—NH₃—H₂O₂ that is effective to remove organic contaminants and particles from the surface of the wafer.

Conditions of forming the seed layer at Step 104 include temperature ranging from 20 to 350° C., preferably from 100 to 300° C.; pressure ranging from 0 to 100 Torr, preferably from 1 to 20 Torr; exposure time ranging from 0.5 min to 60 min, preferably from 1 to 30 min. An inert gas selected from N₂, Ar, He or the like may be added to the surface preparative Si-containing precursors, and preferably, the inert gas is N₂. The temperature of the Step 104 are an important parameter and are chosen to enhance the reactivity of the surface preparative Si-containing precursor towards the surface (physisorption or chemisorption) especially the reactivity towards surface hydroxyls (—OH). The upper range of the temperature is chosen to not decompose or pyrolyze the surface preparative Si-containing precursor such that it reacts with the surface and does not decompose to cause contamination.

Deposition conditions of the disclosed method for forming the doped amorphous Si-containing ultrathin (nanosheet) conformal and continuous film are as follows. Deposition temperature ranges from 20 to 700° C., preferably from 300 to 600° C. The deposition temperature is critical to form a highly conformal film. Deposition pressure ranges from 0 to 100 Torr, preferably from 1 to 20 Torr. An inert gas selected from N₂, Ar, He, H₂, Kr, Xe, Ne may be used as a carrier gas to be added to the surface preparative Si-containing precursors and the dopant precursor. Preferably, the inert gas is N₂. Flow rates may vary depending on what type of chamber applied. Dopant precursor PH₃, AsH₃, P(SiH₃)₃, P(Si₂H₅)₃, As(SiH₃), As(SiH₃)₃ or P(SiH₃)₂(Si₂H₅) may be applied for n-type doping; dopant precursor BF₃, B₂H₆, B₅H₉ or BCl₃ may be used for p-type doping, or more generally X—R₃ where X is As, P, or B; R is H, F, Cl, Br, any C₁-C₅ hydrocarbon, or SiH₃. Dopant ratio (P to Si) is enough to achieve levels of 1E17 to 1E20 of doping, preferably, 1E18 to 1E19.

In the air break step (Step 108) of the disclosed method, temperature ranges from 15 to 30° C., preferably from 18 to 25° C. Room Humidity (RH) ranges from 0 to 100%, preferably 30-65%. Air break time may range from 1 minute to 48 hours, preferably from 10 to 20 hours. Those skilled in the art will understand that this step may be modified in a different controlled moisture or air exposure process.

Upon obtaining a desired film thickness of the deposited doped amorphous Si-containing nanosheet, the deposited nanosheet may be subject to further processing, such as thermal annealing at Step 110. Other annealing processes, such as furnace-annealing, rapid thermal annealing, UV e-beam or laser curing (single or multiple pulses at different wavelength of light), and/or plasma gas exposure may also be applied. Those skilled in the art recognize the systems and methods utilized to perform these additional processing steps. For example, the deposited nanosheet may be exposed to a temperature ranging from approximately 200° C. to approximately 1200° C. and a pressure ranging from 0 to 100 Torr for a time ranging from approximately 1 microseconds to 24 hours under an inert atmosphere such as N₂ or a forming gas (4% H₂ and 96% N₂). Preferably, the temperature ranges 300 to 850° C.; more preferably 650° C. Preferably, the pressure ranges from 1 to 760 Torr. Preferably, the annealing time ranges for 6 to 15 hours; and preferably, the deposited film is exposed to the forming gas.

The nanosheets formed by the disclosed methods typically have a continuous thickness ranging from approximately 2 nm to approximately 100 nm, preferably 2 to 35 nm, more preferably ranging from approximately 2 nm to approximately 20 nm, even more preferably ranging from approximately 2 nm to approximately 10 nm, most preferably from approximately 2 nm to approximately 5 nm. The conformality of the deposited nanosheets ranges from 80 to 100%, preferably from 90 to 100%. The roughness (Rq) of the deposited nanosheets ranges from 0 to 1 nm, preferably 0-0.5 nm. The contamination (such as C, N, etc.) of the deposited nanosheets ranges from 0 to 1E20, preferably 0 to 1E19 or less. The dopant of the deposited nanosheets ranges from 1E17 to 1E20, preferably from 1E18 to 1E19. A bulk resistivity of the deposited nanosheets at room temperature is less than 0.2 ohm·cm.

The deposited nanosheet may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the deposited nanosheet. This in turn tends to improve the resistivity of the deposited nanosheet.

After annealing, the deposited nanosheet deposited by any of the disclosed processes may have a bulk resistivity at room temperature of less than 0.2 ohm·cm. Room temperature is approximately 20° C. to approximately 28° C. depending on the season. Bulk resistivity is also known as volume resistivity across a defined film thickness. One of the ordinary skill in the art will recognize that the bulk resistivity is measured at room temperature on the deposited nanosheets that are typically approximately 20 nm thick. The bulk resistivity typically increases for thinner films due to changes in the electron transport mechanism. The bulk resistivity also increases at higher temperatures.

Here is an embodiment showing an optimal deposition conditions. A 3 um thick SiO₂/Si substrate is prepared and cleaned using Standard Clean 1 wet cleaning chemistry (SC-1). The substrate is then loaded into a quartz tube reactor immediately after SC-1 cleaning. The substrates is heated to 400° C. for 30 minutes under 700 sccm of N₂ flow at a pressure of 9.5 Torr. The substrates is then cooled to 200° C. and exposed to (diisobutylamino)trisilane at a flow of ˜2 sccm and 698 sccm of N₂ for 10 minutes. Afterward, the substrates is heated up to 410° C. under 700 sccm of N₂ flow at 9.5 Torr pressure and exposed to a mixture of trisilane at a flow of about 2 sccm, 1% PH₃ at a flow of about 3 sccm and N₂ at a flow of 697 sccm for about 4 hrs. The substrates is then taken out of the quartz tube reactor and exposed to air to form a native oxide layer on the substrate for about 16 hrs. The substrates is loaded back to the quartz tube reactor and annealed at 650° C. under a forming gas flow of 1000 sccm at 750 Torr for 10 hrs.

The disclosed method is different from WO 2021/257927 and the disclosed method discloses using (diisobutylamino)trisilane as a seed layer forming precursor to deposit a Si seed layer on top of the substrate which is only for growth enhancement but not for final nanosheet property enhancements such as resistivity, grain size, roughness and the like. WO 2021/257927 does not disclose specific annealing process and annealing conditions. The disclosed method demonstrates that (diisobutylamino)trisilane as a seed layer precursor followed by a main deposition using (diisobutylamino)trisilane or trisilane shows improvement in grain size and resistivity of the deposited nanosheet. This indicates that the exposure of extremely thin monolayer of (diisobutylamino)trisilane on the substrate before the main deposition may improve crystal growing properties. These properties require a post deposition anneal turning the amorphous deposited polysilicon layer to a crystalline silicon layer with enhanced electrical properties. In addition, the chosen deposition temperature for the main deposition step is critical for high film conformality.

The disclosed method shows, from Examples that follow, that a deposition temperature of greater than or equal to 450° C. may result in non-conformal films when deposited using LPCVD and contaminants when deposited at temperature of 460° C. or greater. In WO 2021/257927 an annealing process is applied after wet coating in Example 11. Therefore, process conditions or deposition conditions are critical to obtain conformal films with good electrical properties. The disclosed method also shows that specific annealing conditions result in low resistivity in the final crystalline nanosheets.

In addition, the disclosed method comprises a vapor exposure of a surface preparative Si-containing precursor (e.g., (diisobutylamino)trisilane) to form a monolayer of the silicon precursor (e.g., the surface preparative Si-containing precursor) on the surface, which is a few atom thickness of silicon containing film. The few atom thickness of silicon containing film is then used as a seed layer followed by a main deposition using a second silicon-containing precursor such as trisilane or (diisobutylamino)trisilane on top of the seed layer and an annealing process. The seed layer is formed by vapor exposure of the monolayer of the silicon precursor on the surface to form a few Si atom thick layer as seed.

The disclosed method shows that a proper combination of deposition conditions, including pressure for conformality, temperature for contaminants and flow rate, etc., is necessary. Examples that follow show that the deposition of a conformal film in a patterned wafer may not work under all conditions as well as temperature may play a significant role in incorporation of contaminants in the film. Substrate temperature may also play a significant role in nonuniformity of the deposited film.

### EXAMPLES

The following non-limiting examples are provided to further illustrate embodiments of the invention. However, the examples are not intended to be all inclusive and are not intended to limit the scope of the inventions described herein.

The following experiments were performed with the conditions listed above and the resulting resistivity of the film or nanosheet are listed in Table 1.

RESISTIVITY MEASUREMENT: Resistivity of blanket films were measured using a 4 point probe Jandel RM3000+ with probe spacing of 1 mm. Bulk resistivity (for a semi-infinite volume) is p having the following formula

$$ρ = ( 2 s π * V ) / I ohm \cdot cm \qquad ( 1 )$$

where the spacing of the probe is s in cm where s=0.1 cm, I=test current, V=measured voltage. Sheet resistance (a measure of resistance of thin films that are nominally uniform in thickness) for wafers and films is Rₛ where

$${R}_{s} = 4.532 * V / I ohm / square \qquad ( 2 )$$

Dividing equation (1) and equation (2): Rₛ=ρ*4.532/0.628 ohms/square. Bulk resistivity for wafers and films is ρ where ρ=Rₛ*t ohm·cm, where t is the film thickness in cm.

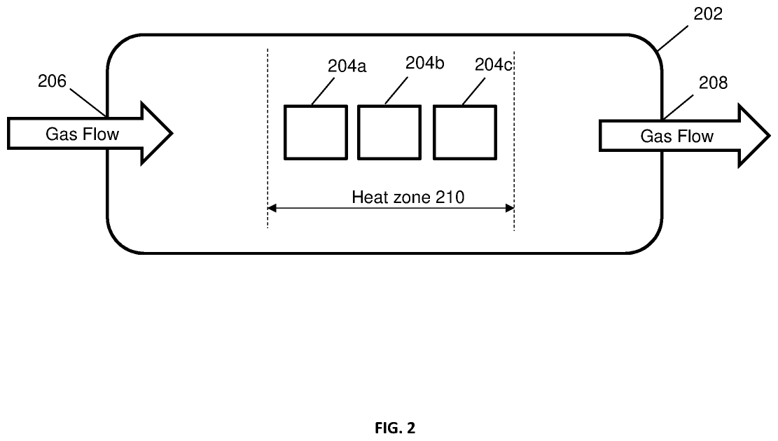

DESCRIBE THE TOOL: a 2″ Quartz tube (12″ single zone) hot walled CVD reactor 202 was used, as shown in FIG. 2, a cross sectional view of the reactor along the central axis of the reactor 202. As shown, substrates 204a, 204b and 204c are placed on a substrate holder (not shown) in heat zone 210 in the reactor 202. Substrates 204a, 204b and 204c each may be a row of substrates containing several substrates. Precursors are introduced into the reactor 202 from a gas inlet 206 as either vapor draw or bubbler using N₂ or other gases as inert gas, and flowed out from a gas outlet 208. Precursor's canisters may be heated to provide sufficient vapor pressure to deliver vapor to the reactor. Vacuum is provided by a dry vacuum pump after the CVD reactor.

XRD was measured using a Bruker D8 Discover model A25.

### Example 1

A series of depositions were performed with Trisilane or (diisobutylamino)trisilane in a LPCVD to deposit a conformal, continuous, smooth crystalline polysilicon film with low resistivity by using an appropriately designed hot walled CVD reactor. A 2″ quartz tube hot walled CVD reactor with a 12″ single heating zone was used where the flow of silicon precursors trisilane or (diisobutylamino)trisilane along with PH₃ as a P dopant were injected into the reactor at various flow rates, pressures and temperatures. After deposition an annealing step may be performed under a variety of gases such as H₂ or N₂ or mixtures of H₂/N₂ to further crystallize the films at various pressures, flows, temperatures and time.

a) A SC-1 cleaned thermal SiO₂ on silicon substrate chemical vapor deposition was done using trisilane and 1% PH₃/N₂ gas mixture at 410° C. at a pressure of 9.5 Torr for ˜220 min followed by a post deposition anneal at 650° C. for 10 hrs, 760 Torr under 4% H₂. The final film thickness was 30-35 nm.

b) A SC-1 cleaned thermal SiO₂ on silicon substrate chemical vapor deposition was done using (diisobutylamino)trisilane and 1% PH₃/N₂ gas mixture at 410° C. at a pressure of 9.5 Torr for ˜165 min followed by a post deposition anneal at 650° C. for 10 hrs, 760 Torr under 4% H₂. The final film thickness was 30-35 nm.

c) A SC-1 cleaned thermal SiO₂ on silicon substrate was heated to 400° C. at 9.5 Torr under nitrogen for 30 min. The silicon substrate was then exposed to a vapor exposure of trisilane for 5 minutes at 200° C. followed by a chemical vapor deposition was done on the substrate using (diisobutylamino)trisilane and 1% PH₃/N₂ gas mixture at 410° C. at a pressure of 9.5 Torr for ˜165 min followed by a post deposition anneal at 650° C. for 10 hrs, 760 Torr under 4% H₂. The final film thickness was 30-35 nm.

d) A SC-1 cleaned thermal SiO₂ on silicon substrate was heated to 400° C. at 9.5 Torr under nitrogen for 30 min. The silicon substrate was then exposed to a vapor exposure of trisilane for 5 minutes at 200° C. followed by a chemical vapor deposition was done on the substrate using trisilane and 1% PH₃/N₂ gas mixture at 410° C. at a pressure of 9.5 Torr for ˜220 min followed by a post deposition anneal at 650° C. for 10 hrs, 760 Torr under 4% H₂. The final film thickness was 30-35 nm.

e) A SC-1 cleaned thermal SiO₂ on silicon substrate was heated to 400° C. at 9.5 Torr under nitrogen for 30 min. The silicon substrate was then exposed to a vapor exposure of (diisobutylamino)trisilane for 5 minutes at 200° ° C. followed by a chemical vapor deposition was done on the substrate using (diisobutylamino)trisilane and 1% PH₃/N₂ gas mixture at 410° C. at a pressure of 9.5 Torr for ˜165 min followed by a post deposition anneal at 650° C. for 10 hrs, 760 Torr under 4% H₂. The final film thickness was 30-35 nm.

f) A SC-1 cleaned thermal SiO₂ on silicon substrate was heated to 400° C. at 9.5 Torr under nitrogen for 30 min. The silicon substrate was then exposed to a vapor exposure of (diisobutylamino)trisilane for 5 minutes at 200° C. followed by a chemical vapor deposition was done on the substrate using trisilane and 1% PH₃/N₂ gas mixture at 410° C. at a pressure of 9.5 Torr for ˜220 min followed by a post deposition anneal at 650° C. for 10 hrs, 760 Torr under 4% H₂. The final film thickness was 30-35 nm.

g) A SC-1 cleaned thermal SiO₂ on silicon substrate was heated to 200° C. at 9.5 Torr under nitrogen for 30 min. The silicon substrate was then exposed to a vapor exposure of (diisobutylamino)trisilane for 5 minutes at 200° C. followed by a chemical vapor deposition was done on the substrate using (diisobutylamino)trisilane and 1% PH₃/N₂ gas mixture at 410° C. at a pressure of 9.5 Torr for ˜165 min followed by a post deposition anneal at 650° C. for 10 hrs, 760 Torr under 4% H₂. The final film thickness was 30-35 nm.

h) A SC-1 cleaned thermal SiO₂ on silicon substrate was heated to 200° ° C. at 9.5 Torr under nitrogen for 30 min. The silicon substrate was then exposed to a vapor exposure of (diisobutylamino)trisilane for 5 minutes at 200° ° C. followed by a chemical vapor deposition was done on the substrate using trisilane and 1% PH₃/N₂ gas mixture at 410° C. at a pressure of 9.5 Torr for ˜220 min followed by a post deposition anneal at 650° C. for 10 hrs, 760 Torr under 4% H₂. The final film thickness was 30-35 nm.

TABLE 1

| Conditions | Film resistivity (Ω · cm) |
|---|---|
| a) | 0.03 |
| b) | 0.08 |
| c) | 0.15 |
| d) | 0.03 |
| e) | 0.07 |
| f) | 0.01 |
| g) | 0.10 |
| h) | 0.02 |

Phosphorus level by SIMs analysis was ˜4-5E19 for all samples with an Rq of <0.5 nm as measured by AFM. As can be seen by experiments a) & b) both (diisobutylamino)trisilane and trisilane precursors and produce a crystalline Si film with resistivity <0.1 Ω·cm. However due to the nature of the structure of trisilane being only composed of Si and H the resistivity was lower thanks to less contaminants in the film. The experiments c) & d) as compared to a & b show that a vapor exposure of trisilane prior to the main deposition using either (diisobutylamino)trisilane or trisilane did not have an appreciable effect on the resistivity. Therefore, trisilane is not an effective surface preparative silicon-containing precursor (seed). On the other hand comparing experiments e) & f) to c) & d) show a noticeable reduction in the film resistivity by the use of an (diisobutylamino)trisilane pre-deposition vapor exposure for both (diisobutylamino)trisilane and trisilane as the main deposition precursor. This critical improvement in the film properties demonstrating that the vapor exposure of (diisobutylamino)trisilane is reacting with the surface, forming a seed layer and improving the resulting final film resistivity likely due to improving the nucleation sites, crystallinity or quality of the final film as compared to using trisilane as the seed precursor. Therefore, (diisobutylamino)trisilane is a more effective surface preparative silicon containing precursor (seed) as compared to trisilane. Experiments i) & j) as compared to e) & h) is primarily to change the surface hydroxyl density on the silicon substrate prior to exposure to the (diisobutylamino)trisilane vapor. There is a minor change in film resistivity with the lower temperature which further corroborates the idea that a vapor exposure of (diisobutylamino)trisilane is reacting with the surface hydroxyls to form a seed layer whereby a higher quality crystalline Si film is formed in the bulk film deposition.

### Example 2

A CVD was performed on a SC-1 cleaned thermal SiO₂ on silicon substrate where a flow of (diisobutylamino)trisilane through the reactor at 410° C. for 14 min under 9.5 Torr resulted in a continuous Si film of 2.7 nm as measured by TEM.

### Example 3

A CVD was performed on a SC-1 cleaned thermal SiO₂ on silicon substrate where a flow of trisilane through the reactor at 410° C. for 33 min at 9.5 Torr resulted in a continuous Si film of 4.5 nm as measured by TEM.

### Example 4

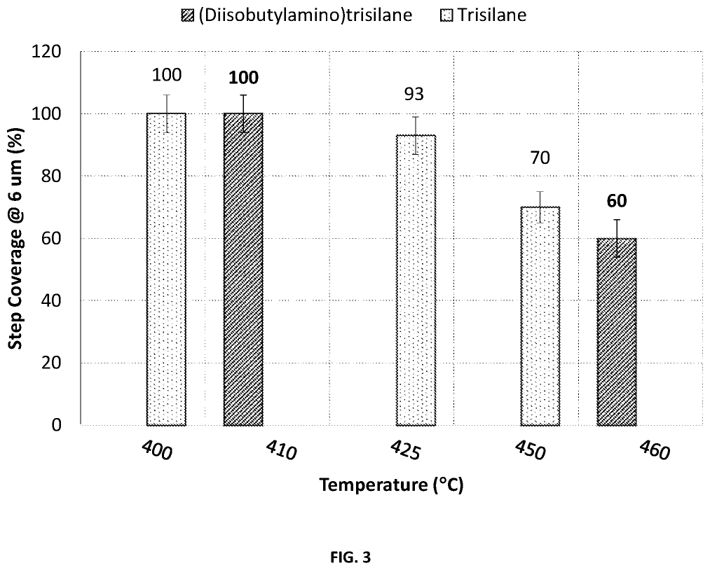

Reactor conditions such as temperature greatly affect step coverage of the Si deposition. Depositions were performed at 400, 425 and 450° C. for trisilane and 410 and 450° C. for (diisobutylamino)trisilane with a flow rate of 2.5 sccm and a flow rate of N₂ of 700 sccm and a reactor pressure of 9.5 Torr, on a patterned wafer 50 nm thermal SiO₂ on Si substrate with a 6 um depth, CD=0.25 um and 20:1 aspect ratio. As shown in FIG. 3, at temperatures above 410° ° C. the step coverage starts to decrease.

### Example 5

Deposition temperature may affect film impurities for silicon precursors where a higher temperature may result in more contaminants due to molecule decomposition, where the elements of the ligands may be incorporated into the film. Contaminants, especially carbon is known to greatly affect film electrical properties. A SC-1 cleaned thermal SiO₂ on silicon substrate was placed in a LPCVD furnace. (diisobutylamino)trisilane was injected into the reactor at a flow rate of 1.6 sccm, pressure of 9.5 Torr, and a temperature of 410° C. or 460° C. Table 2 shows the carbon and nitrogen contaminant level measured using SIMs analysis as a function of deposition temperature as well as after a post deposition anneal in a 4% H₂/N₂ atmosphere for 30 min at 850° C.

TABLE 2

| Deposition | Carbon | Carbon | Nitrogen pre- | Nitrogen |
|---|---|---|---|---|
| temperature | pre-anneal | post-anneal | anneal | post-anneal |
| (° C.) | (atm/cm³) | (atm/cm³) | (atm/cm³) | (atm/cm³) |
| 410 | 3.25E20 | 1.66E20 | 4.74E19 | 3.62E18 |
| 460 | 7.86E20 | 6.86E20 | 1.20E20 | 8.24E19 |

As may be seen from the results the carbon contamination was 2 times higher at 460° ° C. deposition temperature and nitrogen was ˜2.5 times higher at 460° C. consistently showing higher contaminants at deposition temperature greater than 410° C. Post anneal in H₂/N₂ environment may help reduce the carbon and nitrogen contaminants however cannot overcome the impact of deposition temperature. Therefore to produce a crystalline film of improved electrical properties would require to limit the deposition temperature below 460° ° C. using (diisobutylamino)trisilane.

### Example 6

A SC-1 cleaned thermal SiO₂ on silicon substrate was placed in a LPCVD reactor. Trisilane was introduced into the reactor at a flow rate of 2.5 sccm, pressure of 9.5 Torr, and temperature of 410° C. Table 3 shows the carbon, nitrogen contaminant level and phosphorus doping level measured using SIMs analysis as a function of flow rate of 1% PH₃/N₂ gas mixture. As can be seen from the table the carbon and nitrogen contaminants are all <1E19 and the phosphorus doping concentration can be controlled by the flow rate of the 1% PH₃/N₂ gas. As trisilane is a carbon and nitrogen free molecule any contamination is background contamination from the tool itself.

TABLE 3

| Flow rate of | | | |
|---|---|---|---|
| 1% PH₃/N₂ (sccm) | C (atm/cm³) | N (atm/cm³) | P (atm/cm³) |
| 1 | 7.65E18 | 6.34E17 | 1.85E19 |
| 3 | 6.22E18 | 2.71E17 | 5.01E19 |
| 5 | 9.64E18 | 2.74E17 | 1.26E20 |

### Example 7

A SC-1 cleaned thermal SiO₂ on silicon substrate was placed in a LPCVD reactor and a CVD was performed on the substrate by introducing into the reactor (diisobutylamino)trisilane or trisilane at 410° C. at a pressure of 9.5 Torr. In both cases the silicon films as deposited were amorphous and no peaks were observed in the XRD.

### Example 8

A SC-1 cleaned thermal SiO₂ on silicon substrate was heated to 400° C. at 9.5 Torr under nitrogen for 30 min. The silicon substrate was then exposed to a vapor exposure of (diisobutylamino)trisilane or trisilane for 5 minutes at 200° ° C. followed by a chemical vapor deposition was done on the substrate using (diisobutylamino)trisilane or trisilane as shown in Table 4 and 1% PH₃/N₂ gas mixture at 410° C. at a pressure of 9.5 Torr followed by a post deposition anneal at 650° C. for 10 hrs, 760 Torr under 4% H₂.

TABLE 4

| | Ellipso | | XRD |
|---|---|---|---|
| | Thickness | 4 pt probe | crystallite size |
| Deposition conditions | (nm) | (Ω · cm) | (nm) |
| (diisobutylamino)trisilane seed + | 32.9 | 0.073 | 23.5 |
| (diisobutylamino)trisilane main | | | |
| deposition | | | |
| (diisobutylamino)trisilane seed + | 30.6 | 0.013 | 24.2 |
| trisilane main deposition | | | |
| trisilane seed + | 33.7 | 0.032 | 22.7 |
| trisilane main deposition | | | |

A small but measurable improvement in the resistivity and the crystallite size as measured using XRD utilizing the Scherrer equation by using a seed of (diisobutylamino)trisilane followed by (diisobutylamino)trisilane or trisilane main deposition as compared to using trisilane as a seed precursor.

### Example 9

A 20 nm Si film was deposited on a SiN membrane using trisilane in a LPCVD reactor at 410° C., a pressure of 9.5 Torr and a flow rate of 1% PH₃/N₂ such that the P concentration was ˜1E19 followed by a post deposition anneal at 650° C. for 10 hrs under an environment of 4% H₂ in N₂ at 760 Torr. Electron Backscatter diffraction (EBSD) was performed using Symmetry Transmission Kikuchi Diffraction (TKD) and an average grain size of ˜460 nm was measured. The same deposition was performed on a SiO₂ on Si substrate and a resistivity of 0.14 Ω·cm and a hall mobility of 5 cm²/(V*s) was obtained.

### Example 10

This example shows the effect of post deposition annealing process on the resulting crystalline Si film electrical properties such as film resistivity. A SC-1 cleaned thermal SiO₂ on silicon substrate was exposed to a vapor exposure of (diisobutylamino)trisilane for 5 minutes at 200° C. followed by a CVD was done on the substrate using trisilane and 1% PH₃/N₂ gas mixture at 410° C. at a pressure of 9.5 Torr followed by a post deposition anneal at 650° C. for 10 hrs, 9.5 Torr under 4% H₂ or 850° C. for 30 min, 9.5 Torr under 4% H₂. Table 5 shows the resistivity of the two films annealed under the two different conditions.

TABLE 5

| | Resistivity 4 pt |
|---|---|
| Annealing conditions | probe (Ω · cm) |
| 650° C. for 10 hrs, 9.5 Torr under 4% H₂ | 0.028 |
| 850° C. for 30 min, 9.5 Torr under 4% H₂. | 0.164 |

As may be seen from the results the annealing conditions have a significant impact on the final crystallinity of the film as shown by the film resistivity. A lower annealing temperature for a longer time results in a lower resistivity.

### Example 11

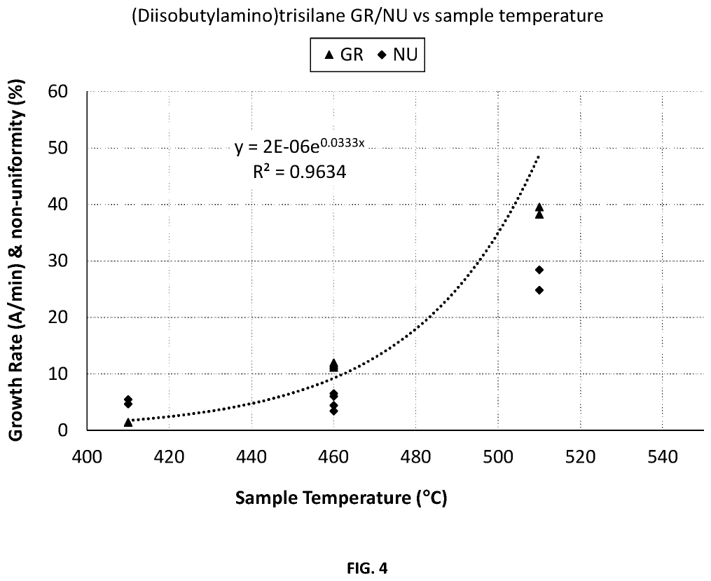

This example shows that specific conditions in this case the substrate temperature may have a large impact on the film non-uniformity where non-uniformity across the wafer is defined as non-uniformity=((max thickness−min thickness)/(max thickness+min thickness))*100. A thermal SiO₂ on silicon substrate was placed in a LPCVD reactor and (diisobutylamino)trisilane was injected at a pressure of 9.5 Torr for 36 minutes with a flow rate of 1.6 sccm and a total N₂ flow of 700 sccm at various substrate temperatures. As may be seen from FIG. 4 as the substrate temperature increases the deposition rate and the % non-uniformity of the wafer increase, especially it substantially increases at temperatures greater than 460° C. Therefore, to minimize the non-uniformity it is preferred to maintain the substrate during deposition to 460° C. or less.

### Comparative Example 1

As a comparison to US20140187024 a comparison between dipropylaminosilane (DIPAS) and (diisobutylamino)trisilane as a first Si-containing precursor or a surface preparative Si-containing precursor for forming a seed layer was performed.

a) A SC-1 cleaned thermal SiO₂ on silicon substrate chemical vapor deposition was done using trisilane and 1% PH₃/N₂ gas mixture at 410° ° C. at a pressure of 9.5 Torr for ˜220 min followed by a post deposition anneal at 650° C. for 10 hrs, 760 Torr under 4% H₂.

b) A SC-1 cleaned thermal SiO₂ on silicon substrate was heated to 400° C. at 9.5 Torr under nitrogen for 30 min. The silicon substrate was then exposed to a vapor exposure of (diisobutylamino)trisilane for 5 minutes at 200° C. followed by a chemical vapor deposition was done on the substrate using trisilane and 1% PH₃/N₂ gas mixture at 410° C. at a pressure of 9.5 Torr for ˜220 min followed by a post deposition anneal at 650° C. for 10 hrs, 760 Torr under 4% H₂.

c) A SC-1 cleaned thermal SiO₂ on silicon substrate was heated to 400° C. at 9.5 Torr under nitrogen for 30 min. The silicon substrate was then exposed to a vapor exposure of (diisobutylamino)trisilane for 5 minutes at 200° ° C. followed by a chemical vapor deposition was done on the substrate using trisilane and 0.01% PH₃/N₂ gas mixture at 410° C. at a pressure of 9.5 Torr for ˜220 min followed by a post deposition anneal at 650° ° C. for 10 hrs, 760 Torr under 4% H₂.

d) A SC-1 cleaned thermal SiO₂ on silicon substrate was heated to 400° C. at 9.5 Torr under nitrogen for 30 min. The silicon substrate was then exposed to a vapor exposure of DIPAS for 5 minutes at 200° C. followed by a chemical vapor deposition was done on the substrate using trisilane and 1% PH₃/N₂ gas mixture at 410° C. at a pressure of 9.5 Torr for ˜220 min followed by a post deposition anneal at 650° ° C. for 10 hrs, 760 Torr under 4% H₂.

e) A SC-1 cleaned thermal SiO₂ on silicon substrate was heated to 400° ° C. at 9.5 Torr under nitrogen for 30 min. The silicon substrate was then exposed to a vapor exposure of DIPAS for 5 minutes at 200° C. followed by a chemical vapor deposition was done on the substrate using trisilane and 0.01% PH₃/N₂ gas mixture at 410° C. at a pressure of 9.5 Torr for ˜220 min followed by a post deposition anneal at 650° C. for 10 hrs, 760 Torr under 4% H₂.

In Table 6 below the film resistivity was measured by 4 point probe and the crystallite size was measured by XRD for each condition a-e.

TABLE 6

| Conditions | Film resistivity (Ω · cm) | Crystallite Size (nm) |
|---|---|---|
| a | 0.03 | 20.3 |
| b | 0.01 | 24.2 |
| c | 0.13 | 19.7 |
| d | 0.04 | 16.5 |
| e | 0.17 | 16.7 |

As can be seen from the results, in conditions a vs d and e that the DIPAS seeding step made both the film resistivity and the crystallite size worse. In addition, in comparing conditions b & c vs conditions d & e that the (diisobutylamino)trisilane gave consistently improved (lower) film resistivity and larger crystallite size under comparable process conditions. DIPAS contains one Si atom and diisobutylamino)trisilane contains 3 Si atoms. The comparison shows that having more than one silicon atom in the first Si precursor along with a reactive group such as an amino group for the seed process is critical to produce improved electrical properties and larger crystallite size of the crystalline silicon film.

Although the subject matter described herein may be described in the context of illustrative implementations to process one or more computing application features/operations for a computing application having user-interactive components the subject matter is not limited to these particular embodiments. Rather, the techniques described herein may be applied to any suitable type of user-interactive component execution management methods, systems, platforms, and/or apparatus.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A method of forming a conformal and continuous crystalline Si film on a surface of a substrate, the method comprising:
i) exposing the substrate to a vapor of a first Si-containing precursor under a first temperature;
ii) allowing a seed film being formed onto the surface;
iii) exposing the substrate to a vapor of a second Si-containing precursor and a vapor of a dopant precursor under a second temperature;
iv) depositing a doped amorphous Si-containing film onto the seed film by a chemical vapor deposition (CVD) process; and
v) annealing the substrate to crystalize the doped amorphous Si-containing film forming the conformal and continuous crystalline Si film on the surface.

2. The method of claim 1, further comprising
prior to annealing the substrate at v), exposing the substrate to air to form a native oxide layer on the doped amorphous Si-containing film.

3. The method of claim 1, further comprising
prior to exposing the substrate at i), cleaning the surface of the substrate with SC-1, HF, RC-1, or RC-2; and
heating the substrate to an elevated temperature, wherein the first temperature is lower than the elevated temperature.

4. The method of claim 1, wherein the first Si-containing precursor has a general formula: 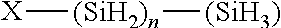
wherein n=1 to 4; X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.

5. The method of claim 1, wherein the first Si-containing precursor is selected from (diisobutylamine)trisilane ((iBu)₂-N—(SiH₂)₂—SiH₃), 1,1,1,2,2,2-hexachlorodisilane ((SiCl₃)₂, HCDS, CAS No.: 13465-77-5) or X-substituted polysilanes or trisilylamines, wherein X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.

6. The method of claim 1, wherein the first Si-containing precursor is (diisobutylamine)trisilane ((iBu)₂-N—(SiH₂)₂—SiH₃) has the following structure:

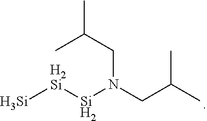

7. The method of claim 1, wherein the second Si-containing precursor has a general formula: 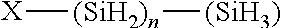
wherein n=0 to 4; X=H, a halogen selected from F, Cl, Br or I, or —NR₂ where R is a C₁ to C₆ linear or branched alkyl group, a C₃-C₆ cyclic alkyl group, a C₂ to C₆ linear or branched alkenyl group, a C₃-C₆ cyclic alkenyl group.

8. The method of claim 1, wherein the second Si-containing precursor is selected from silane, disilane, trisilane, tetrasilane, pentylsilane, (diisobutylamino)trisilane ((iBu)₂-N—(SiH₂)₂—SiH₃), 1,1,1,2,2,2-hexachlorodisilane ((SiCl₃)₂, HCDS, CAS No.: 13465-77-5), or dichlorosilane (H₂SiCl₂, DCS, CAS No.: 4109-96-0).

9. The method of claim 1, wherein the second Si-containing precursor is trisilane.

10. The method of claim 1, wherein the dopant precursor is carried by an inert gas and selected from PH₃, AsH₃, P(SiH₃)₃, P(Si₂H₅)₃, As(SiH₃), As(SiH₃)₃, P(SiH₃)₂(Si₂H₅), BF₃, B₂H₆, B₅H₉ or BCl₃.

11. The method of claim 1, wherein the doped amorphous Si-containing film on the seed film is conformal.

12. The method of claim 1, wherein the conformal and continuous crystalline Si film has a continuous thickness ranging from approximately 2 to approximately 35 nm.

13. The method of claim 1, wherein the conformal and continuous crystalline Si film has a resistivity of about 0.2 Ω·cm or less and grain size of 20 nm or greater.

14. The method of claim 1, wherein an electrical dopant in the conformal and continuous crystalline Si film ranges from about 1E17 to 1E20 atoms/cm³.

15. The method of claim 1, wherein the first temperature ranges from 20° C. to 350° C.

16. The method of claim 1, wherein the second temperature ranges from 20° C. to 700° C.

17. The method of claim 1, wherein a deposition pressure ranges from 0 to 100 Torr.

18. A method of forming a conformal and continuous crystalline Si film on a surface of a substrate, the method comprising:
a) exposing the substrate to a vapor of (diisobutylamino)trisilane at a temperature of 200° C.;
b) allowing a Si-containing seed film being formed onto the surface;
c) exposing the substrate to a vapor of trisilane and 1% PH₃ gas carried by N₂ at a temperature of 410° C.;
d) depositing a doped amorphous Si-containing film onto the Si-containing seed film by a chemical vapor deposition (CVD) process; and
e) annealing the substrate under a temperature 650° ° C. to crystalize the doped amorphous Si-containing film forming the conformal and continuous crystalline Si film on the surface.

19. The method of claim 18, further comprising
prior to annealing the substrate at v), exposing the substrate to air to form a native oxide layer on the doped amorphous Si-containing film.

20. The method of claim 18, further comprising
prior to exposing the substrate at i), cleaning the surface of the substrate with SC-1; and
heating the substrate to a temperature of 400° C.
